(19) United States
(12) Patent Application Publication
(10) Pub. No.: US 2025/0022904 A1
(43) Pub. Date: Jan. 16, 2025

(54) IMAGE SENSORS AND METHODS OF FABRICATING THE SAME

(71) Applicant: Samsung Electronics Co., Ltd., Suwon-si (KR)

(72) Inventors: Mingwan Cho, Daejeon (KR); Jonghwa Shin, Daejeon (KR); Joonkyo Jung, Daejeon (KR); Shin Ho Lee, Suwon-si, Gyeonggi-do (KR); Min Sung Heo, Suwon-si, Gyeonggi-do (KR)

(73) Assignee: Korea Advanced Institute of Science and Technology, Daejeon (KR)

(21) Appl. No.: 18/732,941

(22) Filed: Jun. 4, 2024

(30) Foreign Application Priority Data
Jul. 12, 2023 (KR) 10-2023-0090395
Oct. 25, 2023 (KR) 10-2023-0143904

(51) Int. Cl. H01L 27/146; H01L 31/105

(52) U.S. Cl. CPC H01L 27/14647; H01L 27/14607; H01L 31/105

(57) ABSTRACT

An image sensor pixel includes first, second and third PIN photodiodes having respective first, second and third widths, which are unequal to each other, and respective first, second and third absorption spectra associated therewith, which are unequal to each other. The first absorption spectra is a first linear combination of three color matching functions divided by a wavelength of light incident the image sensor, the second absorption spectra is a second linear combination of the three color matching functions divided by a wavelength of light incident the image sensor, and the third absorption spectra is a third linear combination of the three color matching functions divided by a wavelength of light incident the image sensor.

### REFERENCE TO PRIORITY APPLICATION

This application claims priority under 35 U.S.C. 119 to Korean Patent Application No. 10-2023-0090395, filed Jul. 12, 2023, and Korean Patent Application No. 10-2023-0143904, filed Oct. 25, 2023, the disclosures of which are hereby incorporated herein by reference.

### BACKGROUND

### 1. Technical Field

The present inventive concept relates to image sensors and methods for fabricating the same. More specifically, the present inventive concept relates to image sensors that use a meta structure and methods for fabricating the same.

### 2. Description of the Related Art

An image sensor is a type of semiconductor element that converts received optical information into electrical signals. In recent years, with a constant demand for microminiaturization of image sensors having high resolution and high sensitivity, there has been a limit to the miniaturization of image sensors using color filters. For example, since the color filters selectively transmit light of a specific color, there is a problem of low light utilization efficiency. Further, it is typically difficult to reduce a thickness of an image sensor using a microlens, a color filter, an antireflection film, or the like to several micrometers or less. In order to solve such problems, image sensors using meta surfaces or meta structures are being researched.

### SUMMARY

Aspects of the present inventive concept provide image sensors that have high resolution and high sensitivity, and are microminiaturized.

Aspects of the present inventive concept also provide methods for fabricating image sensors that have high resolution and high sensitivity, and are microminiaturized.

However, aspects of the present inventive concept are not restricted to the ones set forth herein. The above and other aspects of the present inventive concept will become more apparent to one of ordinary skill in the art to which the present inventive concept pertains by referencing the detailed description of the present inventive concept given below.

According to some aspects of the present inventive concept, there is provided an image sensor including a plurality of unit pixels arranged two-dimensionally, wherein each of the unit pixels includes a first PIN photodiode having a first width, a second PIN photodiode having a second width different from the first width, and a third PIN photodiode having a third width different from the first width and the second width, and wherein the absorption spectra of the first to third PIN photodiodes are expressed as different independent linear combinations of functions obtained by dividing each of three color matching functions by wavelength.

According to aspects of the present inventive concept, there is provided an image sensor including a plurality of unit pixels arranged two-dimensionally. Each of the unit pixels includes a first spacer layer on a substrate, a first PIN photodiode on the first spacer layer, a second spacer layer on the first PIN photodiode, a second PIN photodiode which overlaps the first PIN photodiode on the second spacer layer, a third PIN photodiode which overlaps the first PIN photodiode on the second spacer layer, and a transparent electrode layer on the second PIN photodiode and the third PIN photodiode. In addition, the second PIN photodiode may have a first width, and the third PIN photodiode may have a second width different from the first width.

According to further aspects of the present inventive concept, there is provided an image sensor including a substrate, a plurality of first PIN photodiodes, which are arranged on the substrate in a grid pattern along a first direction and a second direction that are parallel to an upper side of the substrate and intersect each other, a plurality of second PIN photodiodes, which are arranged on the substrate in a grid pattern along the first direction and the second direction and are arranged along a third direction between the first direction and the second direction with the plurality of first PIN photodiodes, and a plurality of third PIN photodiodes on the substrate. In addition, each of the third PIN photodiodes may overlap at least one of the plurality of first PIN photodiodes and at least one of the plurality of second PIN photodiodes, and a first width of each of the first PIN photodiodes may be different from a second width of each of the second PIN photodiodes.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a block diagram for explaining an image sensor according to some embodiments.

FIG. 2 is a layout diagram for explaining an image sensor according to some embodiments.

FIG. 3 is a cross-sectional view taken along line A-A of FIG. 2.

FIG. 4 is a diagram for explaining the operation of the image sensor shown in FIGS. 2 and 3.

FIGS. 5 to 8 are graphs for explaining an absorption spectrum of a unit pixel of the image sensor according to some embodiments.

FIGS. 9 to 11 are diagrams based on a computer simulation that explain light absorption of the unit pixel of the image sensor according to some embodiments.

FIG. 12 is a cross-sectional view for explaining an image sensor according to some embodiments.

FIG. 13 is a layout diagram for explaining an image sensor according to some embodiments.

FIG. 14 is a layout diagram for explaining an image sensor according to some embodiments.

FIG. 15 is a cross-sectional view taken along line B-B of FIG. 14.

FIG. 16 is a layout diagram for explaining an image sensor according to some embodiments.

FIG. 17 is a cross-sectional view taken along line C-C of FIG. 16.

FIGS. 18 to 28 are intermediate stage diagrams for explaining a method for fabricating an image sensor according to some embodiments.

### DETAILED DESCRIPTION OF THE EMBODIMENTS

It will be understood that, although the terms first, second, third, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

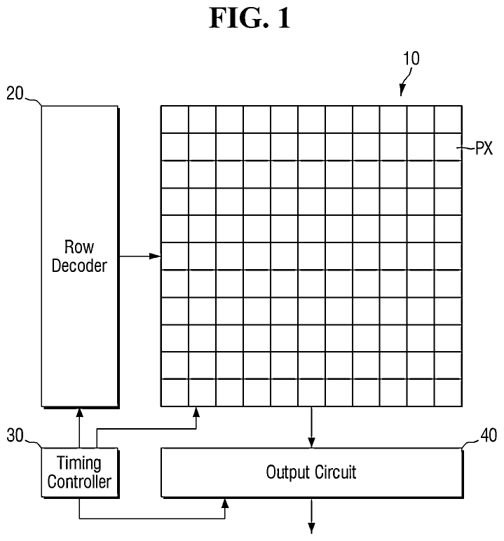

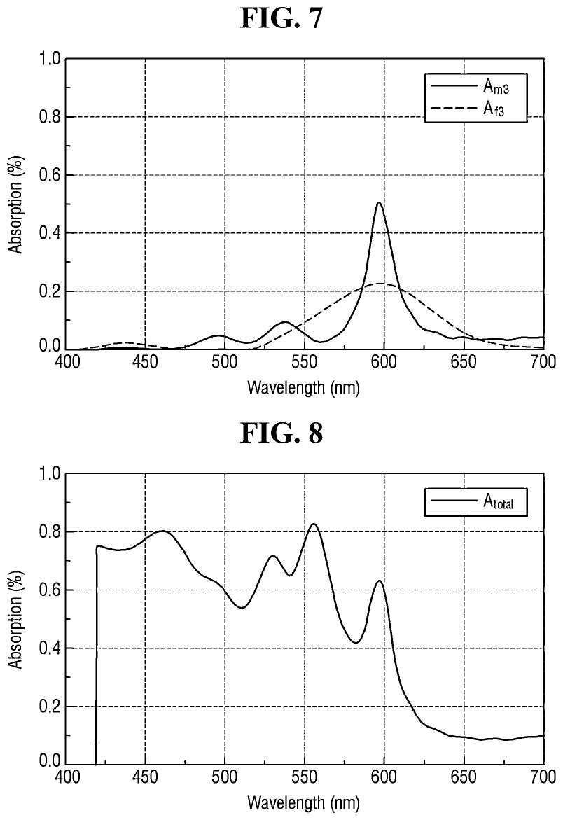

An image sensor according to exemplary embodiments will be described below with reference to FIGS. 1 to 17. FIG. 1 is a block diagram for explaining an image sensor according to some embodiments. Referring to FIG. 1, the image sensor according to some embodiments may include a pixel array 10, a row decoder 20, a timing controller 30, and an output circuit 40. The pixel array 10 may include a plurality of unit pixels PX which are arranged two-dimensionally along a plurality of rows and a plurality of columns. Each unit pixel PX may convert an optical signal into an electrical signal.

The row decoder 20 may select one of the rows of the pixel array 10 in response to a row address signal that is output from the timing controller 30. The output circuit 40 may output light-sensing signals in units of columns from a plurality of pixels arranged along a selected row. For example, the output circuit 40 may include a column decoder and an analog-to-digital converter (ADC). The output circuit 40 may include a plurality of ADCs disposed for each column between the pixel array 10 and the column decoder, and may include one ADC disposed at an output terminal of the column decoder. The row decoder 20, the timing controller 30, and the output circuit 40 may each be implemented as one chip or on separate chips. Alternatively, the processor for processing an image signal which is output through the output circuit 40 may be implemented as a single chip together with the row decoder 20, the timing controller 30, and the output circuit 40.

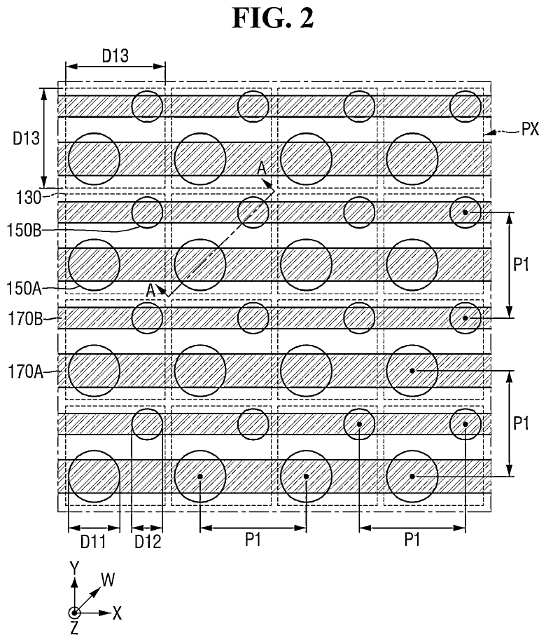

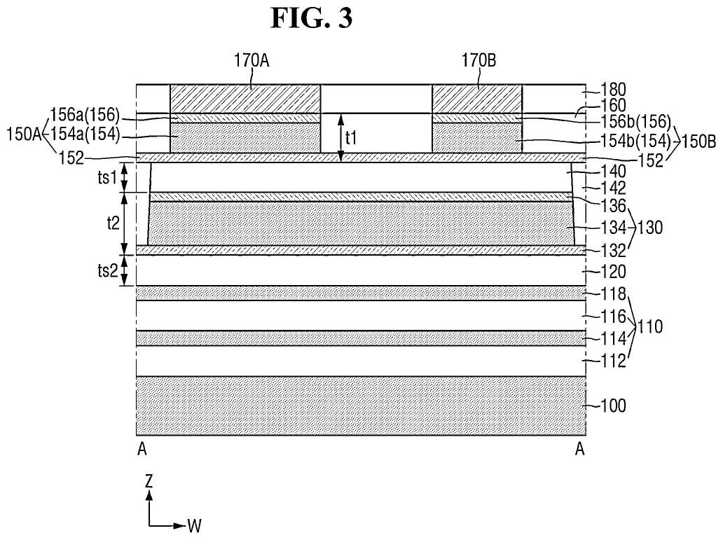

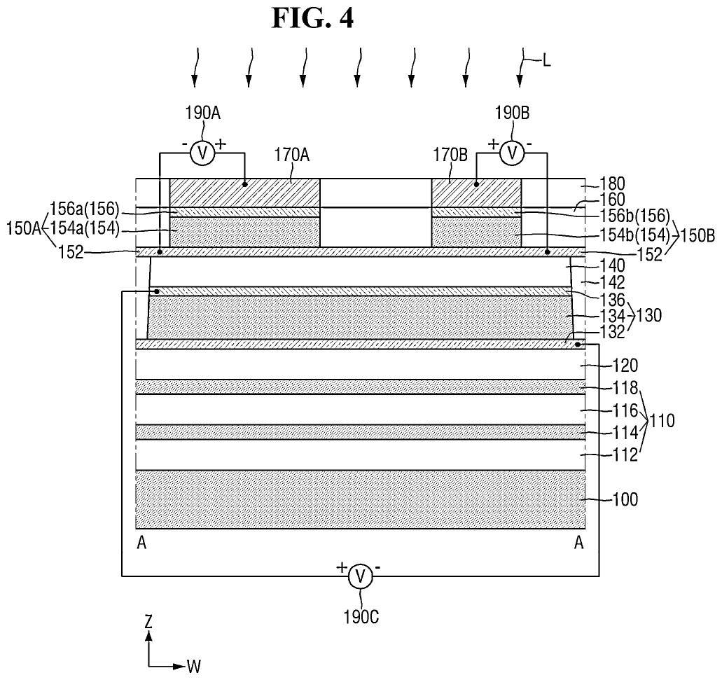

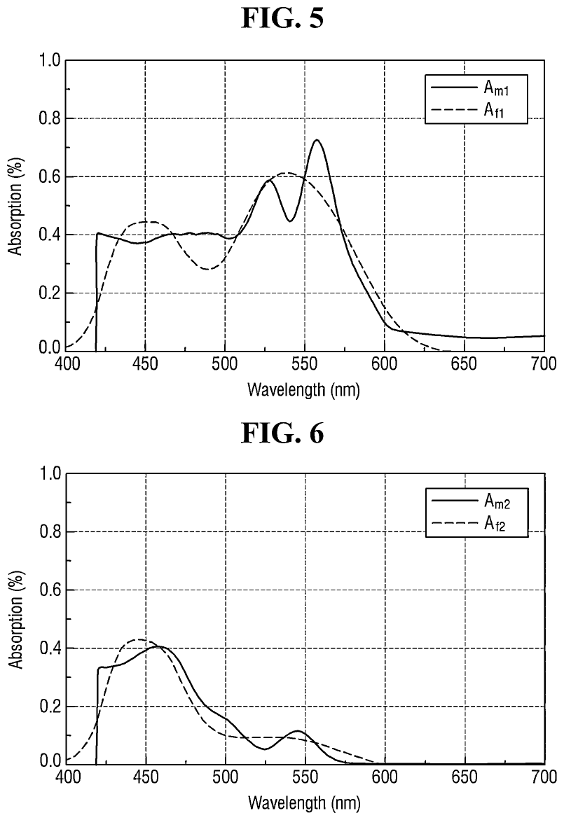

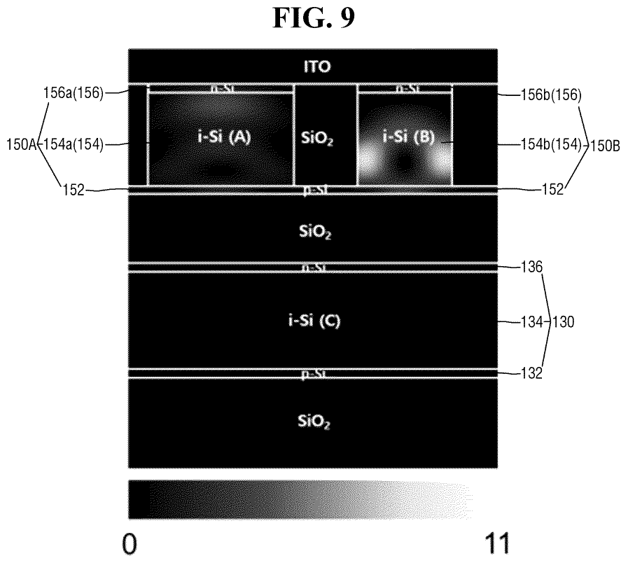

FIG. 2 is a layout diagram for explaining an image sensor according to some embodiments. FIG. 3 is a cross-sectional view taken along line A-A of FIG. 2. FIG. 4 is a diagram for explaining the operation of the image sensor shown in FIGS. 2 and 3. FIGS. 5 to 8 are graphs for explaining an absorption spectrum of a unit pixel of the image sensor according to some embodiments. FIGS. 9 to 11 are diagrams shown using a computer simulation for explaining light absorption of the unit pixel of the image sensor according to some embodiments.

Referring to FIGS. 2 to 11, an image sensor according to some embodiments may include a substrate 100, a reflective structure 110, a first PIN photodiode 150A, a second PIN photodiode 150B, a third PIN photodiode 130, and transparent electrode layers 170A and 170B. The substrate 100 may be a semiconductor substrate, such as bulk silicon or a silicon-on-insulator (SOI). The substrate 100 may be a silicon substrate, or may include other materials, for example, silicon germanium, indium antimonide, lead telluride, indium arsenide, indium phosphide, gallium arsenide or gallium antimonide. Alternatively, the substrate 100 may be one in which an epitaxial layer is formed on a base substrate.

A plurality of unit pixels PX arranged two-dimensionally may be formed on the substrate 100. For example, the unit pixels PX may be arranged two-dimensionally (e.g., in the form of a matrix) along a first direction X and a second direction Y that are parallel to an upper side of the substrate 100 and intersect each other. In some embodiments, the first direction X and the second direction Y may be orthogonal to each other. The unit pixels PX are arranged at a first period P1 smaller than a wavelength of visible ray (e.g., about 400 nm to about 700 nm), and may form a meta structure on the substrate 100. For example, the first period P1 at which the unit pixels PX are arranged may be about 400 nm or less.

In some embodiments, the substrate 100 may include circuit elements that process electrical signals provided from each unit pixel PX. For example, the substrate 100 may include electrodes and/or wiring patterns electrically connected to each unit pixel PX. The circuit elements may include logic elements including an analog circuit and/or a digital circuit, and may include a memory element for storing data. The logic element and the memory element may be formed in different layers or the same layer. The circuit elements may include various circuit elements shown in FIG. 1.

The reflective structure 110 may be formed on the substrate 100. The reflective structure 110 may include a Distributed Bragg reflector (DBB). For example, the reflective structure 110 may have a multilayer structure in which first reflective layers 112 and 115 and second reflective layers 114 and 118 having different refractive indexes from each other are alternately stacked. As an example, the first reflective layers 112 and 115 may include a silicon oxide film, and the second reflective layers 114 and 118 may include a silicon film, but the embodiment is not limited thereto.

A third PIN photodiode 130 may be formed on the reflective structure 110. The third PIN photodiode 130 may be spaced apart from the reflective structure 110 by a first spacer layer 120. For example, the first spacer layer 120 may be formed on the upper side of the reflective structure 110, and the third PIN photodiode 130 may be formed on the upper side of the first spacer layer 120. The first spacer layer 120 may include an insulating material, for example, but not limited to, at least one of silicon oxide, silicon nitride, silicon oxynitride, and combinations thereof. As an example, the first spacer layer 120 may include silicon oxide film (SiO₂).

The third PIN photodiode 130 may include a p-i-n junction. For example, the third PIN photodiode 130 may include a first impurity semiconductor layer 132, a first intrinsic semiconductor layer 134, and a second impurity semiconductor layer 136, which are sequentially stacked on the first spacer layer 120. The first impurity semiconductor layer 132 may contain an impurity of a first conductivity type, and the second impurity semiconductor layer 136 may contain an impurity of a second conductivity type different from the first conductivity type. The first intrinsic semiconductor layer 134 may be interposed between the first impurity semiconductor layer 132 and the second impurity semiconductor layer 136, and may include an intrinsic semiconductor material that is not doped with impurities. In the following description, an example in which the first conductivity type is a p-type and the second conductivity type is an n-type will be described. As an example, the first impurity semiconductor layer 132 may be p-Si (p-doped Si), the first intrinsic semiconductor layer 134 may be i-Si (intrinsic Si), and the second impurity semiconductor layer 136 may be n-Si (n-doped Si). However, this is only an example, and it goes without saying that the first conductivity type may be an n-type and the second conductivity type may be a p-type.

A thickness of the first impurity semiconductor layer 132 and a thickness of the second impurity semiconductor layer 136 may each be, for example, about 15 nm or less. In some embodiments, the thickness of the first impurity semiconductor layer 132 and the thickness of the second impurity semiconductor layer 136 may each be about 10 nm or less to improve the absorption rate of the first intrinsic semiconductor layer 134. For example, each of the thickness of the first impurity semiconductor layer 132 and the thickness of the second impurity semiconductor layer 136 may be about 1 nm to about 10 nm.

In some embodiments, the third PIN photodiode 130 may include polycrystalline silicon (Si). For example, the first impurity semiconductor layer 132 may be formed by doping a p-type impurity (e.g., boron (B), aluminum (Al) or gallium (Ga)) under polycrystalline silicon, and the second impurity semiconductor layer 136 may be formed by doping an n-type impurity (e.g., phosphorus (P), arsenic (As) or antimony (Sb)) above polycrystalline silicon. Because the polycrystalline silicon is advantageous to a doping process in comparison to amorphous silicon (Si) and has a high absorption coefficient in comparison to single crystalline silicon, it may be suitable for PIN photodiodes.

In some embodiments, an element isolation pattern 142 that defines a plurality of third PIN photodiodes 130 arranged two-dimensionally may be formed. The element isolation pattern 142 may extend in a fourth direction Z intersecting the upper side of the substrate 100 to cut the first intrinsic semiconductor layer 134 and the second impurity semiconductor layer 136. For example, the lower side of the element isolation pattern 142 may be formed to be lower than or equal to the lower side of the first intrinsic semiconductor layer 134, and the upper side of the element isolation pattern 142 may be formed to be higher than or equal to the upper side of the second impurity semiconductor layer 136. Although it is only shown that the element isolation pattern 142 does not cut the first impurity semiconductor layer 132, this is only an example, and the element isolation pattern 142 may, of course, cut the first impurity semiconductor layer 132.

The first PIN photodiode 150A and the second PIN photodiode 150B may be formed on the third PIN photodiode 130. The first PIN photodiode 150A and the second PIN photodiode 150B may be spaced apart from the third PIN photodiode 130 by the second spacer layer 140. For example, the second spacer layer 140 may be formed on the upper side of the third PIN photodiode 130, and the first PIN photodiode 150A and the second PIN photodiode 150B may be formed on the upper side of the second spacer layer 140. The second spacer layer 140 may include an insulating material, for example, but not limited to, at least one of silicon oxide, silicon nitride, silicon oxynitride, and combinations thereof. As an example, the second spacer layer 140 may include silicon oxide film (SiO₂).

The first PIN photodiode 150A and the second PIN photodiode 150B may each include a p-i-n junction. For example, the first PIN photodiode 150A and the second PIN photodiode 150B may each include a third impurity semiconductor layer 152, a second intrinsic semiconductor layer 154, and a fourth impurity semiconductor layer 156, which are sequentially stacked on the second spacer layer 140. The third impurity semiconductor layer 152 may contain the impurity of the first conductivity type (e.g., p-type), and the fourth impurity semiconductor layer 156 may contain the impurity of the second conductivity type (e.g., n-type). The second intrinsic semiconductor layer 154 may be interposed between the third impurity semiconductor layer 152 and the fourth impurity semiconductor layer 156, and may include an intrinsic semiconductor material that is not doped with impurities. As an example, the third impurity semiconductor layer 152 may be p-Si (p-doped Si), the second intrinsic semiconductor layer 154 may be i-Si (intrinsic Si), and the fourth impurity semiconductor layer 156 may be n-Si (n-doped Si).

Each of a thickness of the third impurity semiconductor layer 152 and a thickness of the fourth impurity semiconductor layer 156 may be, for example, about 15 nm or less. In some embodiments, each of the thickness of the third impurity semiconductor layer 152 and the thickness of the fourth impurity semiconductor layer 156 may be about 10 nm or less to improve the absorption rate of the second intrinsic semiconductor layer 154. For example, each of the thickness of the third impurity semiconductor layer 152 and the thickness of the fourth impurity semiconductor layer 156 may be about 1 nm to about 10 nm.

In some embodiments, each of the first PIN photodiode 150A and the second PIN photodiode 150B may include polycrystalline silicon (Si). For example, the third impurity semiconductor layer 152 may be formed by doping a p-type impurity (e.g., boron (B), aluminum (Al) or gallium (Ga)) under polycrystalline silicon, and the fourth impurity semiconductor layer 156 may be formed by doping an n-type impurity (e.g., phosphorus (P), arsenic (As) or antimony (Sb)) above polycrystalline silicon.

The first PIN photodiode 150A and the second PIN photodiode 150B may be disposed at the same level. In this specification, the expression “disposed at the same level” means that both are disposed at the same height on the basis of the upper side of the substrate 100. For example, the first PIN photodiode 150A and the second PIN photodiode 150B may be arranged along a third direction W between the first direction X and the second direction Y.

In some embodiments, the third impurity semiconductor layer 152 of the first PIN photodiode 150A and the third impurity semiconductor layer 152 of the second PIN photodiode 150B may be connected to each other. For example, the third impurity semiconductor layer 152 may extend across the first PIN photodiode 150A and the second PIN photodiode 150B, and the first PIN photodiode 150A and the second PIN photodiode 150B may share the third impurity semiconductor layer 152.

The second intrinsic semiconductor layer 154 may include a first sub-intrinsic semiconductor layer 154a and a second sub-intrinsic semiconductor layer 154b, which are spaced apart from each other, and the fourth impurity semiconductor layer 156 may include a first sub-impurity semiconductor layer 156a and a second sub-impurity semiconductor layer 156b, which are spaced apart from each other. The first sub-intrinsic semiconductor layer 154a and the first sub-impurity semiconductor layer 156a may be sequentially stacked on the third impurity semiconductor layer 152 to form the first PIN photodiode 150A. The second sub-intrinsic semiconductor layer 154b and the second sub-impurity semiconductor layer 156b may be spaced apart from the first sub-intrinsic semiconductor layer 154a and the first sub-impurity semiconductor layer 156a in the third direction W, and may be sequentially stacked on the third impurity semiconductor layer 152 to form the second PIN photodiode 150B.

As shown in FIG. 2, each of the first PIN photodiode 150A, the second PIN photodiode 150B, and the third PIN photodiode 130 may have a shape dimension smaller than the wavelength of visible ray, and may be arranged two-dimensionally and periodically. In some embodiments, the plurality of first PIN photodiodes 150A may have a first period P1 and may be arranged in a grid pattern along (i.e., that spans) a first direction X and a second direction Y. Here, the first period P1 may be defined as a spaced distance between two adjacent first PIN photodiodes 150A in the first direction X or the second direction Y. As an example, the first period P1 may be defined as, but not limited to, a spaced distance between a center point of one first PIN photodiode 150A and a center point of another first PIN photodiode 150A adjacent thereto. Although each first PIN photodiode 150A is shown to have a cylindrical shape, this is merely an example, and each first PIN photodiode 150A may, of course, have a polygonal pillar shape such as a square pillar or a hexagonal pillar.

In some embodiments, the plurality of second PIN photodiodes 150B may be arranged in a grid pattern along (i.e., that spans) the first direction X and the second direction Y. In some embodiments, the plurality of second PIN photodiodes 150B may be arranged to have the same first period P1 as the first PIN photodiodes 150A. Further, the first PIN photodiodes 150A and the second PIN photodiodes 150B may be arranged alternately along the third direction W (e.g. the grid pattern of the plurality of second PIN photodiodes 150B is offset relative to the grid pattern of the plurality of first PIN photodiodes 150A). For example, the plurality of first PIN photodiodes 150A and the plurality of second PIN photodiodes 150B may form a tetragonal grid structure. In such a case, an acute angle formed between the first direction X and the third direction W may be 45°. Although each second PIN photodiode 150B is shown to have a cylindrical shape, this is merely an example, and needless to say, each second PIN photodiode 150B may have a polygonal pillar shape such as a square pillar or a hexagonal pillar.

In some embodiments, the plurality of third PIN photodiodes 130 may be arranged in a grid pattern along the first direction X and the second direction Y. In some embodiments, the plurality of third PIN photodiodes 130 may be placed at a different level from the first PIN photodiodes 150A and the second PIN photodiodes 150B. For example, each third PIN photodiode 130 may overlap at least one of the plurality of first PIN photodiodes 150A and at least one of the plurality of second PIN photodiodes 150B. Here, the overlap means being disposed to overlap in a fourth direction Z that intersects the upper side of the substrate 100. For example, as described above, both the first PIN photodiodes 150A and the second PIN photodiodes 150B may be placed on the upper sides of the third PIN photodiode 130. In some embodiments, the plurality of third PIN photodiodes 130 may be arranged to have the same first period P1 as the first PIN photodiodes 150A and the second PIN photodiodes 150B. Although each third PIN photodiode 130 is shown to have a square pillar shape, this is only an example, and needless to say, each third PIN photodiode 130 may have a cylindrical shape or various other polygonal pillar shapes.

The first PIN photodiode 150A, the second PIN photodiode 150B, and the third PIN photodiode 130 may have shape dimensions different from each other. For example, the first PIN photodiode 150A may have a first width D11, and the second PIN photodiode 150B may have a second width D12 different from the first width D11. In some embodiments, a first width D11 of the first PIN photodiode 150A may be greater than a second width D12 of the second PIN photodiode 150B. The third PIN photodiode 130 may have a third width D13 different from the first width D11 and the second width D12. In some embodiments, the third width D13 of the third PIN photodiode 130 may be larger than the first width D11 of the first PIN photodiode 150A and the second width D12 of the second PIN photodiode 150B.

Each unit pixel PX may include at least one first PIN photodiode 150A, at least one second PIN photodiode 150B, and at least one third PIN photodiode 130. In some embodiments, each unit pixel PX may include one first PIN photodiode 150A, one second PIN photodiode 150B, and one third PIN photodiode 130. For example, as shown in FIG. 2, a region of the element isolation pattern 142 that defines one third PIN photodiode 130 may define one unit pixel PX.

The transparent electrode layers 170A and 170B may be formed on the first PIN photodiode 150A and the second PIN photodiode 150B. For example, the first interlayer insulating film 160 may be formed on the upper side of the third impurity semiconductor layer 152, the side face of the second intrinsic semiconductor layer 154, and the side face of the fourth impurity semiconductor layer 156. The transparent electrode layers 170A and 170B may extend along the upper side of the first PIN photodiode 150A, the upper side of the second PIN photodiode 150B, and/or the upper side of the first interlayer insulating film 160. The first interlayer insulating film 160 may include, but not limited to, at least one of silicon oxide, silicon nitride, silicon oxynitride, silicon oxycarbide, silicon boronitride, silicon boron carbonitride, silicon oxycarbonitride, and a low dielectric constant material having a dielectric constant lower than that of silicon oxide. As an example, the first interlayer insulating film 160 may include a silicon oxide film (SiO₂).

The transparent electrode layers 170A and 170B may be connected to the fourth impurity semiconductor layer 156. For example, the transparent electrode layers 170A and 170B may include a first transparent electrode pattern 170A connected to the first sub-impurity semiconductor layer 156a, and a second transparent electrode pattern 170B connected to the second sub-impurity semiconductor layer 156b. Accordingly, the transparent electrode layers 170A and 170B may be electrically connected to the first PIN photodiode 150A and the second PIN photodiode 150B. The first transparent electrode pattern 170A and the second transparent electrode pattern 170B may be separated from each other by the second interlayer insulating film 180. For example, the second interlayer insulating film 180 may include, but not limited to, at least one of silicon oxide, silicon nitride, silicon oxynitride, silicon oxycarbide, silicon boronitride, silicon boron carbonitride, silicon oxycarbonitride, and a low dielectric constant material having a dielectric constant lower than that of silicon oxide. As an example, the second interlayer insulating film 180 may include a silicon oxide film (SiO₂).

In some embodiments, the first transparent electrode pattern 170A may extend long in the first direction X, and may be connected to a plurality of first PIN photodiodes 150A arranged along the first direction X. In some embodiments, the second transparent electrode pattern 170B may extend long in the first direction X, and may be connected to a plurality of second PIN photodiodes 150B arranged along the first direction X. The transparent electrode layers 170A and 170B may include transparent conductive materials. For example, the transparent electrode layers 170A and 170B may include, but not limited to, at least one of ITO (Indium tin oxide), IZO (Indium Zinc Oxide), ZnO (Zinc oxide), SnO₂ (Tin dioxide), ATO (Antimony-doped tin oxide), AZO (Aluminum-doped zinc oxide), GZO (Galium-doped zinc oxide), TiO₂ (titanium dioxide), FTO (fluorine-doped tin oxide) or combinations thereof.

In some embodiments, the transparent electrode layers 170A and 170B may form an ohmic contact with the fourth impurity semiconductor layer 156. As an example, when the fourth impurity semiconductor layer 156 is n-Si, the transparent electrode layers 170A and 170B may include ITO. As another example, when the fourth impurity semiconductor layer 156 is p-Si, the transparent electrode layers 170A and 170B may include IZO.

The first PIN photodiode 150A, the second PIN photodiode 150B, and the third PIN photodiode 130 may each independently generate charges in proportion to an amount of light incident from the outside, and the generated charges each may be sensed independently through the output circuit (e.g., 40 of FIG. 1). For example, as shown in FIG. 4, a first sensing circuit 190A connected to the first PIN photodiode 150A, a second sensing circuit 190B connected to the second PIN photodiode 150B, and a third sensing circuit 190C connected to the third PIN photodiode 130 may be formed. Various circuit elements shown in FIG. 1 may include a first sensing circuit 190A, a second sensing circuit 190B, and a third sensing circuit 190C.

The first sensing circuit 190A may sense electrons generated from the first sub-intrinsic semiconductor layer 154a through the first sub-impurity semiconductor layer 156a and the first transparent electrode pattern 170A, and the second sensing circuit 190B may sense electrons generated from the second sub-intrinsic semiconductor layer 154b through the second sub-impurity semiconductor layer 156b and the second transparent electrode pattern 170B. Further, the third sensing circuit 190C may sense electrons generated from the first intrinsic semiconductor layer 134 through the second impurity semiconductor layer 136. Holes generated from the second intrinsic semiconductor layer 154 of the first PIN photodiode 150A and the second PIN photodiode 150B may be removed through the third impurity semiconductor layer 152, and the holes generated from the first intrinsic semiconductor layer 134 of the third PIN photodiode 130 may be removed through the first impurity semiconductor layer 132.

In the image sensor according to some embodiments, the absorption spectra A₁(λ), A₂(λ), and A₃(λ) of the first to third PIN photodiodes 150A, 150B, and 130 may be expressed as different independent linear combinations of functions obtained by dividing each of three color matching functions by wavelength λ. For example, the first absorption spectra A₁(λ) of the first PIN photodiode 150A may be expressed as a first linear combination of the three color matching functions divided by wavelength λ of light incident the first PIN photodiode 150A. The second absorption spectra A₂(λ) of the second PIN photodiode 150B may be expressed as a second linear combination of the three color matching functions divided by wavelength λ of light incident the second PIN photodiode 150B. The third absorption spectra A₃(λ) of the third PIN photodiode 130 may be expressed as a third linear combination of the three color matching functions divided by wavelength λ of light incident the third PIN photodiode 130. As will be understood by those skilled in the art, a color matching function is a numerical description of the viewer's color response, and may include, for example, CIE XYZ color matching functions (x̅(λ), y̅(λ), z̅(λ)). When the three color matching functions are CIE XYZ color matching functions ((x̅(λ), y̅(λ), z̅(λ), the absorption spectra A₁(λ), A₂(λ), and A₃(λ) of the first to third PIN photodiodes 150A, 150B, and 130 may be expressed as in Formula 1 below.

$$( \begin{matrix}{A}_{1} ( λ ) \\ {A}_{2} ( λ ) \\ {A}_{3} ( λ )\end{matrix} ) = ( \begin{matrix}{C}_{11} & {C}_{12} & {C}_{13} \\ {C}_{21} & {C}_{22} & {C}_{23} \\ {C}_{31} & {C}_{32} & {C}_{33}\end{matrix} ) ( \begin{matrix}\frac{\overline{x} ( λ )}{λ} \\ \frac{\overline{y} ( λ )}{λ} \\ \frac{\overline{z} ( λ )}{λ}\end{matrix} ) \qquad [ Formula 1 ]$$

In the above Formula (1), C₁₁ to C₃₃ are each constants, and may be determined through an optimization method. For example, predetermined structural variables that determine the absorption spectra A₁(λ), A₂(λ), and A₃(λ) of the first to third PIN photodiodes 150A, 150B, and 130 may be set. In the following description, a first period P1, a width D11 of the first PIN photodiode 150A, a width D12 of the second PIN photodiode 150B, a thickness t1 of the first PIN photodiode 150A and the second PIN photodiode 150B, a thickness ts1 of the second spacer layer 140, a thickness t2 of the third PIN photodiode 130, and a thickness ts2 of the first spacer layer 120 are set and shown as the predetermined structural variables.

The absorption spectra A₁(λ), A₂(λ), and A₃(λ) of the first to third PIN photodiodes 150A, 150B, 130 may be calculated, for example, through a finite-difference time-domain (FDFD) analysis method on the basis of the predetermined structural variables P1, D11, D12, t1, ts1, t2, and ts2. Further, the predetermined structural variables P1, D11, D12, t1, ts1, t2, and ts2 may be optimized such that the absorption spectra A₁(λ), A₂(λ), and A₃(λ) of the first to third PIN photodiodes 150A, 150B, 130 correspond to different independent linear combinations of the functions obtained by dividing each of the three color matching functions by the wavelength λ. For example, the predetermined structural variables P1, D11, D12, t1, ts1, t2, and ts2 and C₁₁ to C₃₃ of Formula 1 may be optimized through an optimization method such as a particle swarm optimization (PSO).

The optimization method may be performed, for example, to minimize a difference between the absorption spectra (hereinafter, Aₘ₁, Aₘ₂, and Aₘ₃) of the first to third PIN photodiodes 150A, 150B, and 130 calculated through the FDFD analysis method and absorption spectra (hereinafter A_{f1}, A_{f2}, and A_{f3}) calculated by different independent linear combinations of the functions obtained by dividing each of the three color matching functions by the wavelength λ within a predetermined wavelength range (e.g., 400 nm to 700 nm). Accordingly, the optimized values of the structural variables P1, D11, D12, t1, ts1, t2, ts2 and the optimized values of C₁₁ to C₃₃ may be derived.

As an example, in FIGS. 5 to 7, solid lines represent the absorption spectra Aₘ₁, Aₘ₂, and Aₘ₃ of the first to third PIN photodiodes 150A, 150B, and 130 calculated through the FDFD analysis method, and dotted lines represent the absorption spectra A_{f1}, A_{f2}, and A_{f3} calculated by different independent linear combinations of functions

$$( \frac{\overline{x} ( λ )}{λ} , \frac{\overline{y} ( λ )}{λ} , \frac{\overline{z} ( λ )}{λ} )$$

obtained by dividing each of CIE XYZ color matching functions by the wavelength λ. Moreover, solid lines of FIG. 8 represent a total absorption spectrum Aₜₒₜₐₗ of the absorption spectra Aₘ₁, Aₘ₂, and Aₘ₃ of the first to third PIN photodiodes 150A, 150B, and 130.

As shown in FIGS. 5 to 7, the absorption spectra Aₘ₁, Aₘ₂, and Aₘ₃ of the first to third PIN photodiodes 150A, 150B, and 130 may be confirmed to fit the absorption spectra A_{f1}, A_{f2}, and A_{f3} calculated by different independent linear combinations of functions

$$( \frac{\overline{x} ( λ )}{λ} , \frac{\overline{y} ( λ )}{λ} , \frac{\overline{z} ( λ )}{λ} )$$

obtained by dividing each of the color matching functions by the wavelength λ through the aforementioned optimization method.

For reference, each of the thicknesses of the first to fourth impurity semiconductor layers 132, 136, 152, and 156 is assumed to be 10 nm in FIGS. 5 to 7. In addition, in FIGS. 5 to 8, the first period P1 is optimized as about 220 nm, the width D11 of the first PIN photodiode 150A is optimized as about 124 nm, the width D12 of the second PIN photodiode 150B is optimized as about 80 nm, the thickness t1 of the first PIN photodiode 150A and the second PIN photodiode 150B is optimized as about 146 nm, the thickness ts of the second spacer layer 140 is optimized as about 95 nm, the thickness t2 of the third PIN photodiode 130 is optimized as about 152 nm, and the thickness ts2 of the first spacer layer 120 is optimized as about 122 nm.

Within the range in which the absorption spectra A₁(λ), A₂(λ), and A₃(λ) of the first to third PIN photodiodes 150A, 150B, and 130 correspond to the different independent linear combinations of the functions obtained by dividing each of the three color matching functions by the wavelength λ, each of the values of the optimized structural variables P1, D11, D12, t1, ts1, t2, and ts2 may have an error range of about 10%. For example, the first period P1 may be about 198 nm to about 242 nm. For example, the width D11 of the first PIN photodiode 150A may be about 111 nm to about 137 nm. For example, the width D12 of the second PIN photodiode 150B may be about 72 nm to about 88 nm. For example, the thickness t1 of the first PIN photodiode 150A and the second PIN photodiode 150B may be about 131 nm to about 161 nm. For example, the thickness ts1 of the second spacer layer 140 may be about 85 nm to about 105 nm. For example, the thickness t2 of the third PIN photodiode 130 may be about 136 nm to about 168 nm. For example, the thickness ts2 of the first spacer layer 120 may be about 109 nm to about 135 nm.

In some embodiments, in order to maintain an effective optical performance, each of the values of the optimized structural variables P1, D11, D12, t1, ts1, t2, and ts2 may have an error range of about 5%. For example, the first period P1 may be about 209 nm to about 231 nm. For example, the width D11 of the first PIN photodiode 150A may be about 117 nm to about 131 nm. For example, the width D12 of the second PIN photodiode 150B may be about 76 nm to about 84 nm. For example, the thickness t1 of the first PIN photodiode 150A and the second PIN photodiode 150B may be about 138 nm to about 154 nm. For example, the thickness ts1 of the second spacer layer 140 may be about 90 nm to about 100 nm. For example, the thickness t2 of the third PIN photodiode 130 may be about 144 nm to about 160 nm. For example, the thickness ts2 of the first spacer layer 120 may be about 115 nm to about 129 nm.

As described above, as the absorption spectra A₁(λ), A₂(λ), and A₃(λ) of the first to third PIN photodiodes 150A, 150B, and 130 are expressed as different independent linear combinations of functions obtained by dividing each of the three color matching functions by the wavelength λ, the color of the incident light that enters the unit pixel PX including the first to third PIN photodiodes 150A, 150B, and 130 may be calculated as tristimulus values representing the human color sense. Accordingly, it possible to provide an image sensor that has high color reproducibility similar to that seen by the human eye, unlike other image sensors that selectively sense light of a specific color by a color filter or the like. Further, as described above, since the unit pixel PX including the first to third PIN photodiodes 150A, 150B, and 130 may be realized by a meta structure arranged at a period smaller than the wavelength of visible ray, it is advantageous for miniaturization compared to other image sensors that require microlenses, color filters, antireflection films, and the like.

Moreover, as shown in FIG. 8, it may be confirmed that all the total absorption spectrum Aₜₒₜₐₗ of the first to third PIN photodiodes 150A, 150B, and 130 show wide and high absorption bandwidths in the red (R), green (G), and blue (B) wavelength ranges. For example, it may be confirmed that the total absorption spectrum Aₜₒₜₐₗ shows about 80% absorption rate in the red (R) wavelength region (e.g., about 460 nm), shows about 82% absorption rate in the green (G) wavelength region (e.g., about 555 nm), and shows about 63% absorption rate in the blue (B) wavelength region (e.g., about 600 nm). Accordingly, it is possible to provide a microminiaturized image sensor having high resolution and high sensitivity even in a low luminance environment.

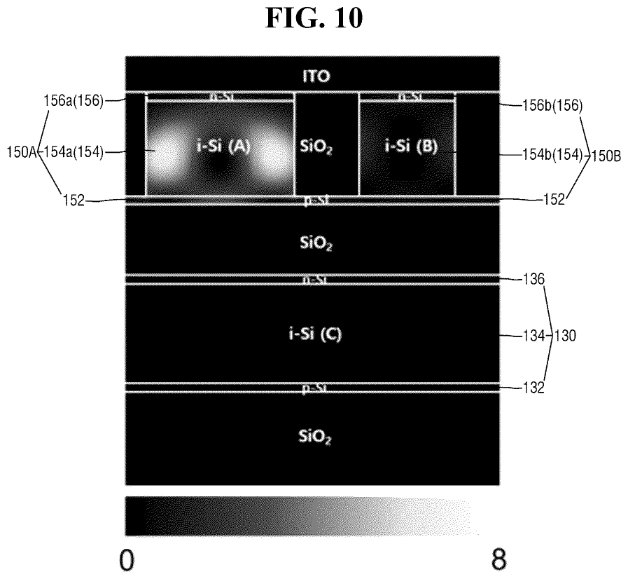

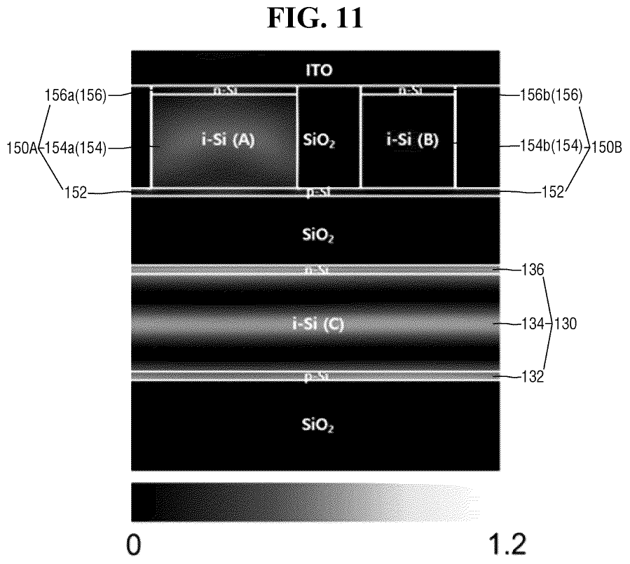

As an example, FIG. 9 shows absorption profiles of the first to third PIN photodiodes 150A, 150B, and 130 in the red (R) wavelength region (about 460 nm), FIG. 10 shows absorption profiles of the first to third PIN photodiodes 150A, 150B, and 130 in the green (G) wavelength region (about 555 nm), and FIG. 11 shows absorption profiles of the first to third PIN photodiodes 150A, 150B, and 130 in the blue (B) wavelength region (about 600 nm). As shown in FIGS. 9 to 11, it may be confirmed that the first to third PIN photodiodes 150A, 150B, and 130 show different absorption profiles in different wavelength regions. For example, in the red (R) wavelength region (about 460 nm) (i.e., in FIG. 9), the first PIN photodiode 150A may show relatively low absorption, the second PIN photodiode 150B may show relatively high absorption, and the third PIN photodiode 130 may show very low absorption. For example, in the green (G) wavelength region (about 555 nm) (i.e., in FIG. 10), the first PIN photodiode 150A may show relatively high absorption, the second PIN photodiode 150B may show relatively low absorption, and the third PIN photodiode 130 may show very low absorption. For example, in the blue (B) wavelength region (about 600 nm) (i.e., in FIG. 11), the first PIN photodiode 150A may show relatively low absorption, the second PIN photodiode 150B may show very low absorption, the third PIN photodiode 130 may show relatively high absorption.

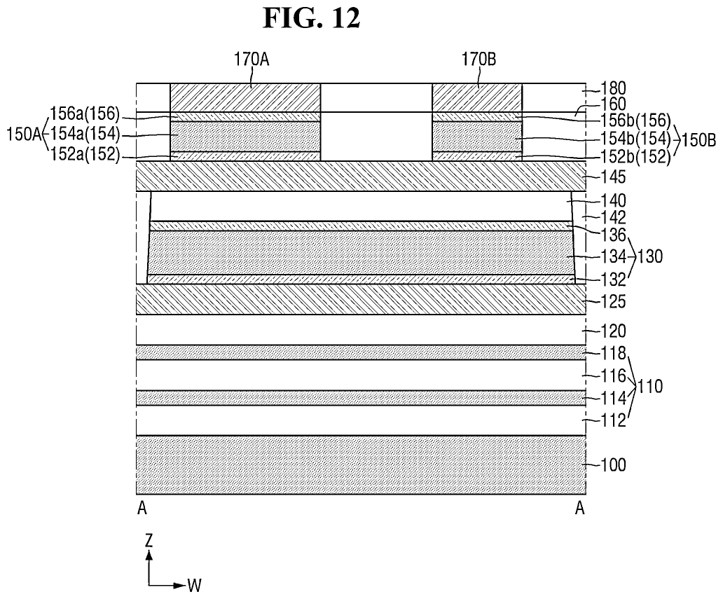

FIG. 12 is a cross-sectional view for explaining an image sensor according to some additional embodiments. For convenience of explanation, repeated parts of those described above using FIGS. 1 to 11 will be briefly explained or omitted. Referring to FIG. 12, the image sensor according to some embodiments may further include a first electrode layer 125 and a second electrode layer 145.

The first electrode layer 125 may be formed below the third PIN photodiode 130. For example, the first electrode layer 125 may extend along the upper side of the first spacer layer 120. The first electrode layer 125 may be connected to the first impurity semiconductor layer 132. Accordingly, the first electrode layer 125 may be electrically connected to the third PIN photodiode 130. In some embodiments, the first electrode layer 125 may extend along a plane including the first direction X and the second direction Y, and may be connected to the third PIN photodiodes 130 of the plurality of unit pixels PX.

In some embodiments, one first impurity semiconductor layer 132 corresponding to one third PIN photodiode 130 may be formed. For example, the element isolation pattern 142 may extend in the fourth direction Z on the first electrode layer 125 to cut the first impurity semiconductor layer 132, the first intrinsic semiconductor layer 134, and the second impurity semiconductor layer 136. The second electrode layer 145 may be formed below the first PIN photodiode 150A and the second PIN photodiode 150B. For example, the second electrode layer 145 may extend along the upper side of the second spacer layer 140 and the upper side of the element isolation pattern 142. The second electrode layer 145 may be connected to the third impurity semiconductor layer 152. Accordingly, the second electrode layer 145 may be electrically connected to the first PIN photodiode 150A and the second PIN photodiode 150B. In some embodiments, the second electrode layer 145 may extend along a plane including the first direction X and the second direction Y, and may be connected to the first PIN photodiodes 150A and the second PIN photodiodes 150B of the plurality of unit pixels PX.

In some embodiments, the third impurity semiconductor layer 152 may include a third sub-impurity semiconductor layer 152a and a fourth sub-impurity semiconductor layer 152b spaced apart from each other. The third sub-impurity semiconductor layer 152a, the first sub-intrinsic semiconductor layer 154a, and the first sub-impurity semiconductor layer 156a may be sequentially stacked on the second electrode layer 145 to form the first PIN photodiode 150A. The fourth sub-impurity semiconductor layer 152b, the second sub-intrinsic semiconductor layer 154b, and the second sub-impurity semiconductor layer 156b may be sequentially stacked on the second electrode layer 145 to form the second PIN photodiode 150B.

The first electrode layer 125 and the second electrode layer 145 may each include a transparent conductive material. For example, the first electrode layer 125 and the second electrode layer 145 may include, but not limited to, at least one of ITO (Indium tin oxide), IZO (Indium Zinc Oxide), ZnO (Zinc oxide), SnO₂ (Tin dioxide), ATO (Antimony-doped tin oxide), AZO (Aluminum-doped zinc oxide), GZO (Gallium-doped zinc oxide), TiO₂ (Titanium dioxide), FTO (Fluorine-doped zinc oxide) or a combination thereof.

In some embodiments, the first electrode layer 125 may form an ohmic contact with the first impurity semiconductor layer 132. As an example, when the first impurity semiconductor layer 132 is p-Si, the first electrode layer 125 may include IZO. In some embodiments, the second electrode layer 145 may form an ohmic contact with the third impurity semiconductor layer 152. As an example, when the third impurity semiconductor layer 152 is p-Si, the second electrode layer 145 may include IZO.

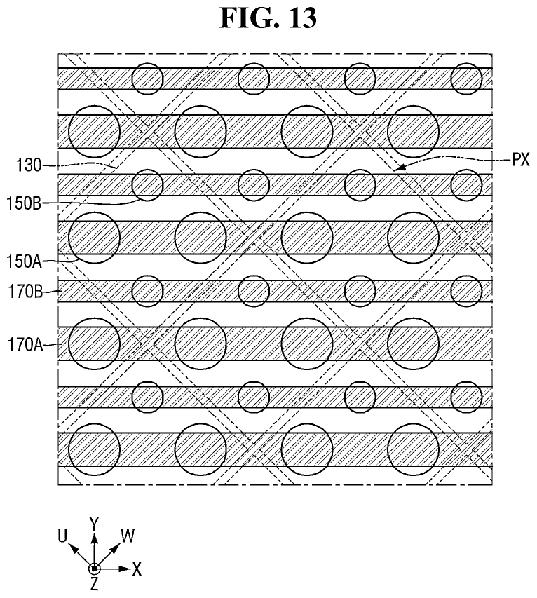

FIG. 13 is a layout diagram for explaining an image sensor according to some embodiments. For convenience of explanation, repeated parts of those described above using FIGS. 1 to 12 will be briefly described or omitted. Referring to FIG. 13, in the image sensor according to some embodiments, each unit pixel PX may include a plurality of first PIN photodiodes 150A and/or a plurality of second PIN photodiodes 150B.

For example, each unit pixel PX may include two first PIN photodiodes 150A, two second PIN photodiodes 150B, and one third PIN photodiode 130. The unit pixels PX may be arranged two-dimensionally (e.g., in the form of a matrix) along the third direction W and a fifth direction U that intersects the third direction W. In some embodiments, the third direction W and the fifth direction U may be orthogonal to each other.

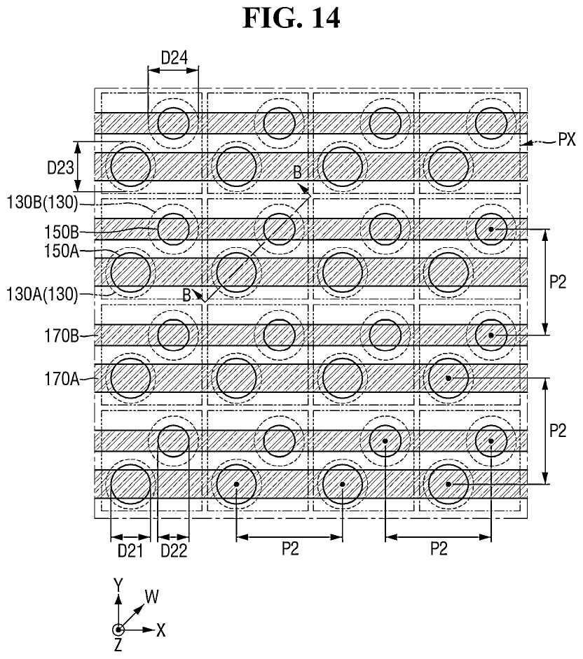

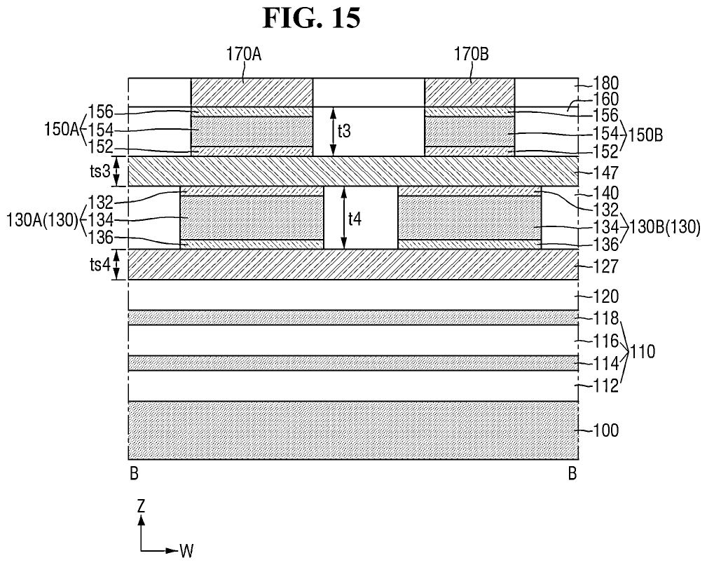

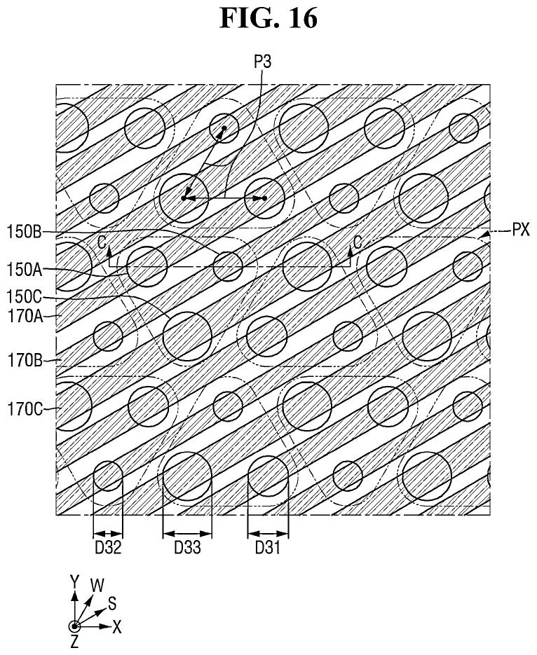

FIG. 14 is a layout diagram for explaining an image sensor according to some embodiments. FIG. 15 is a cross-sectional view taken along line B-B of FIG. 14. For convenience of explanation, repeated parts of those described above using FIGS. 1 to 13 will be briefly explained or omitted.

Referring to FIGS. 14 and 15, in an image sensor according to some embodiments, the third PIN photodiode 130 may include a first sub-PIN photodiode 130A and a second sub-PIN photodiode 130B. Each of the first sub-PIN photodiode 130A and the second sub-PIN photodiode 130B may include a first impurity semiconductor layer 132, a first intrinsic semiconductor layer 134, and a second impurity semiconductor layer 136. In some embodiments, the first impurity semiconductor layer 132 may be opposite to the third impurity semiconductor layer 152. For example, the second impurity semiconductor layer 136, the first intrinsic semiconductor layer 134, and the first impurity semiconductor layer 132 may be sequentially stacked on the first spacer layer 120.

Each unit pixel PX may include a first sub-PIN photodiode 130A and a second sub-PIN photodiode 130B. The first sub-PIN photodiode 130A and the second sub-PIN photodiode 130B may be spaced apart from each other inside each unit pixel PX. The first PIN photodiode 150A may overlap the first sub-PIN photodiode 130A, and the second PIN photodiode 150B may overlap the second sub-PIN photodiode 130B. For example, each unit pixel PX may include one first PIN photodiode 150A, one second PIN photodiode 150B, one first sub-PIN photodiode 130A, and one second PIN photodiode 130B. The unit pixels PX are arranged at a second period P2 smaller than the wavelength of visible ray (e.g., about 400 nm to about 700 nm), and may form a meta structure on the substrate 100.

In some embodiments, a third electrode layer 127 may be formed below the first sub-PIN photodiode 130A and the second sub-PIN photodiode 130B. The third electrode layer 127 may be connected to the second impurity semiconductor layer 136. In some embodiments, a fourth electrode layer 147 may be formed between the first sub-PIN photodiode 130A and the first PIN photodiode 150A, and between the second sub-PIN photodiode 130B and the second PIN photodiode 150B. The fourth electrode layer 147 may be connected to the first impurity semiconductor layer 132 and the third impurity semiconductor layer 152.

Each of the third electrode layer 127 and the fourth electrode layer 147 may include a transparent conductive material. For example, the third electrode layer 127 and the fourth electrode layer 147 may include, but not limited to, at least one of ITO (Indium tin oxide), IZO (Indium Zinc Oxide), ZnO (Zinc oxide), SnO₂ (Tin dioxide), ATO (Antimony-doped tin oxide), AZO (Aluminum-doped zinc oxide), GZO (Gallium-doped zinc oxide), TiO₂ (Titanium dioxide), FTO (Fluorine-doped zinc oxide) or a combination thereof.

In some embodiments, third electrode layer 127 may form an ohmic contact with second impurity semiconductor layer 136. As an example, when the second impurity semiconductor layer 136 is n-Si, the third electrode layer 127 may include ITO. In some embodiments, the fourth electrode layer 147 may form an ohmic contact with the first impurity semiconductor layer 132 and the third impurity semiconductor layer 152. As an example, when each of the first impurity semiconductor layer 132 and the third impurity semiconductor layer 152 is p-Si, the fourth electrode layer 147 may include IZO.

Each of the first sub-PIN photodiode 130A and the second sub-PIN photodiode 130B may have shape dimensions different from those of the first PIN photodiode 150A and the second PIN photodiode 150B. For example, the first PIN photodiode 150A may have a fourth width D21, and the second PIN photodiode 150B may have a fifth width D22, which is different from the fourth width D21. In some embodiments, the fourth width D21 of the first PIN photodiode 150A may be greater than the fifth width D22 of the second PIN photodiode 150B. Each of the first sub-PIN photodiode 130A and the second sub-PIN photodiode 130B may have a sixth width D23 that is different from the fourth width D21 and the fifth width D22. In some embodiments, the sixth width D23 of the first sub-PIN photodiode 130A and the second sub-PIN photodiode 130B may be greater than the fourth width D21 of the first PIN photodiode 150A and the fifth width D22 of the second PIN photodiode 150B.

As described above in the explanation of FIGS. 2 to 11, the absorption spectra A₁(λ), A₂(λ), and A₃(λ) of the first to third PIN photodiodes 150A, 150B, and 130 may be expressed as different independent linear combinations of functions obtained by dividing each of three color matching functions by the wavelength λ. For example, the second period P2, the width D21 of the first PIN photodiode 150A, the width D22 of the second PIN photodiode 150B, the width D23 of the first sub-PIN photodiode 130A and the second sub-PIN photodiode 130B, the thickness t3 of the first PIN photodiode 150A and the second PIN photodiode 150B, the thickness ts3 of the fourth electrode layer 147, the thickness t4 of the first sub-PIN photodiode 130A and the second sub-PIN photodiode 130B, and the thickness ts4 of the third electrode layer 127 may be set as the predetermined structural variables. Next, the values of the structural variables P2, D21, D22, D23, t3, ts3, t4, and ts4 and the optimized values of C₁₁ to C₃₃ may be derived through the aforementioned optimization method.

As an example, the second period P2 may be optimized as about 304 nm, the width D21 of the first PIN photodiode 150A may be optimized as about 106 nm, the width D22 of the second PIN photodiode 150B may be optimized as about 69 nm, the width D23 of the first sub-PIN photodiode 130A and the second sub-PIN photodiode 130B may be optimized as about 127 nm, the thickness t3 of the first PIN photodiode 150A and the second PIN photodiode 150B may be optimized as about 154 nm, the thickness ts3 of the fourth electrode layer 147 may be optimized as about 135 nm, the thickness t4 of the third PIN photodiode 130 may be optimized as about 192 nm, and the thickness ts4 of the third electrode layer 127 may be optimized as about 192 nm.

Within the range in which the absorption spectra A₁(λ), A₂(λ), and A₃(λ) of the first to third PIN photodiodes 150A, 150B, and 130 correspond to the different independent linear combinations of the functions obtained by dividing each of the three color matching functions by the wavelength λ, each of the values of the optimized structural variables P2, D21, D22, D34, t3, ts3, t4, and ts4 may have an error range of about 10%. In some embodiments, each of the values of the optimized structural variables P2, D21, D22, D23, t3, ts3, t4, and ts4 may have an error range of about 5% to maintain an effective optical performance.

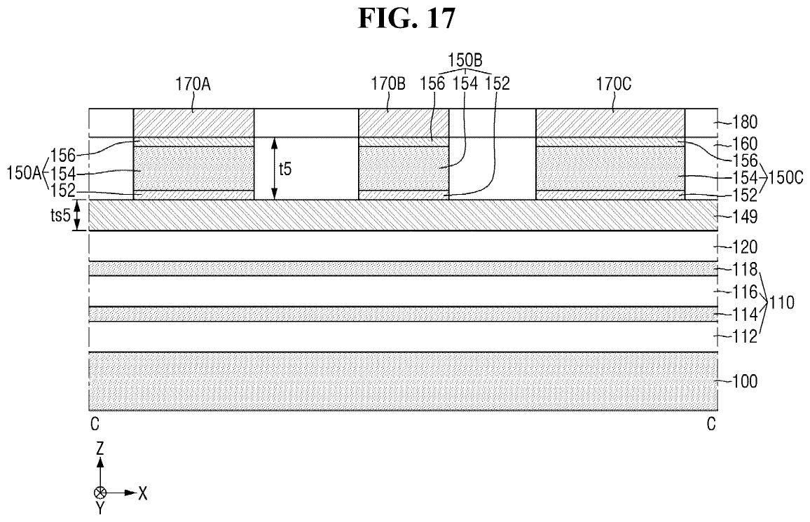

FIG. 16 is a layout diagram for explaining an image sensor according to some embodiments. FIG. 17 is a cross-sectional view taken along line C-C of FIG. 16. For convenience of explanation, repeated parts of those described above using FIGS. 1 to 15 will be briefly explained or omitted. Referring to FIGS. 16 and 17, in the image sensor according to some embodiments, each unit pixel PX may include a first PIN photodiode 150A, a second PIN photodiode 150B, and a fourth PIN photodiode 150C.

The first PIN photodiode 150A, the second PIN photodiode 150B, and the fourth PIN photodiode 150C may be placed at the same level. For example, the first PIN photodiode 150A and the second PIN photodiode 150B may be arranged along the first direction X, and the first PIN photodiode 150A and the fourth PIN photodiode 150C may be arranged along the third direction W. The first PIN photodiode 150A, the second PIN photodiode 150B, and the fourth PIN photodiode 150C may each include a third impurity semiconductor layer 152, a second intrinsic semiconductor layer 154, and a second fourth impurity semiconductor layer 156 which are stacked sequentially.

The unit pixels PX are arranged at a third period P3 smaller than the wavelength of visible ray (e.g., about 400 nm to about 700 nm), and may form a meta structure on the substrate 100. In some embodiments, each unit pixel PX may include one first PIN photodiode 150A, one second PIN photodiode 150B, and one fourth PIN photodiode 150C.

In some embodiments, the plurality of first PIN photodiodes 150A, the plurality of second PIN photodiodes 150B, and the plurality of fourth PIN photodiodes 150C may form a hexagonal grid structure. In such a case, the acute angle formed between the first direction X and the third direction W may be 60°.

In some embodiments, a fifth electrode layer 149 may be formed below the first PIN photodiode 150A, the second PIN photodiode 150B, and the fourth PIN photodiode 150C. The fifth electrode layer 149 may be connected to the third impurity semiconductor layer 152. The fifth electrode layer 149 may include a transparent conductive material. For example, the fifth electrode layer 149 may include, but not limited to, at least one of ITO (Indium tin oxide), IZO (Indium Zinc Oxide), ZnO (Zinc oxide), SnO₂ (Tin dioxide), ATO (Antimony-doped tin oxide), AZO (Aluminum-doped zinc oxide), GZO (Gallium-doped zinc oxide), TiO₂ (Titanium dioxide), FTO (Fluorine-doped zinc oxide) or a combination thereof. In some embodiments, the fifth electrode layer 149 may form an ohmic contact with the third impurity semiconductor layer 152. As an example, when the third impurity semiconductor layer 152 is p-Si, the fifth electrode layer 149 may include IZO.

The first PIN photodiode 150A, the second PIN photodiode 150B, and the fourth PIN photodiode 150C may have different shape dimensions from each other. For example, the first PIN photodiode 150A may have a seventh width D31, and the second PIN photodiode 150B may have an eighth width D32, which is different from the seventh width D31. In some embodiments, the seventh width D31 of the first PIN photodiode 150A may be greater than the eighth width D32 of the second PIN photodiode 150B. The fourth PIN photodiode 150C may have a ninth width D33 that is different from the seventh width D31 and the eighth width D32. In some embodiments, the ninth width D33 of the third PIN photodiode 130 may be greater the seventh width D31 of the first PIN photodiode 150A and the eighth width D32 of the second PIN photodiode 150B.

In some embodiments, the transparent electrode layers 170A, 170B, and 170C may include a first transparent electrode pattern 170A, a second transparent electrode pattern 170B, and a third transparent electrode pattern 170C. The first transparent electrode pattern 170A may be connected to the fourth impurity semiconductor layer 156 of the first PIN photodiode 150A, the second transparent electrode pattern 170B may be connected to the fourth impurity semiconductor layer 156 of the second PIN photodiode 150B, and the third transparent electrode pattern 170C may be connected to the fourth impurity semiconductor layer 156 of the fourth PIN photodiode 150C.

In some embodiments, each of the first transparent electrode pattern 170A, the second transparent electrode pattern 170B, and the third transparent electrode pattern 170C may extend along a sixth direction S between the first direction X and the third direction W. The first transparent electrode pattern 170A may be connected to a plurality of first PIN photodiodes 150A arranged along the sixth direction S. The second transparent electrode pattern 170B may be connected to a plurality of second PIN photodiodes 150B arranged along the sixth direction S. The third transparent electrode pattern 170C may be connected to a plurality of fourth PIN photodiodes 150C arranged along the sixth direction S. When the plurality of first PIN photodiodes 150A, the plurality of second PIN photodiodes 150B, and the plurality of fourth PIN photodiodes 150C form a hexagonal grid structure, an acute angle formed between the first direction and the six directions S may be 30°.

As described above in the explanation of FIGS. 2 to 11, the absorption spectra A₁(λ), A₂(λ), and A₄(λ) of the first, second and fourth PIN photodiodes 150A, 150B, and 150C may be expressed as different independent linear combinations of functions obtained by dividing each of three color matching functions by the wavelength λ. For example, the third period P3, the width D31 of the first PIN photodiode 150A, the width D32 of the second PIN photodiode 150B, the width D33 of the fourth sub-PIN photodiode 150C, the thickness t5 of the first, second and fourth PIN photodiode 150A, 150B, and 150C, and the thickness ts5 of the fifth electrode layer 149 may be set as the predetermined structural variables. Next, the values of the structural variables P3, D31, D32, D33, t5, and ts5 and the optimized values of C₁₁ to C₃₃ may be derived through the aforementioned optimization method.

For example, the third period P3 is about 373 nm, the width D31 of the first PIN photodiode 150A may be optimized as about 82 nm, the width D32 of the second PIN photodiode 150B may be optimized as about 78 nm, the width D33 of the fourth PIN photodiode 150C may be optimized as about 114 nm, the thickness t5 of the first, second and fourth PIN photodiodes 150A, 150B, and 150C may be optimized as about 198 nm, and the thickness ts5 of the fifth electrode layer 149 may be optimized as about 122 nm.

Within the range in which the absorption spectra A₁(λ), A₂(λ), and A₄(λ) of the first, second and fourth PIN photodiodes 150A, 150B, and 150C correspond to the different independent linear combinations of the functions obtained by dividing each of the three color matching functions by the wavelength λ, each of the values of the optimized structural variables P3, D31, D32, D33, t5, and ts5 may have an error range of about 10%. In some embodiments, each of the values of the optimized structural variables P3, D31, D32, D33, t5, and ts5 may have an error range of about 5% to maintain an effective optical performance.

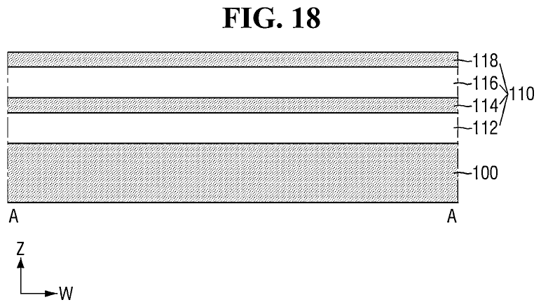

The image sensor according to exemplary embodiments will be described below with reference to FIGS. 1 to 28. In particular, FIGS. 18 to 28 are intermediate stage diagrams for explaining a method for fabricating an image sensor according to some embodiments. For convenience of explanation, repeated parts of those described above using FIGS. 1 to 17 will be briefly explained or omitted.

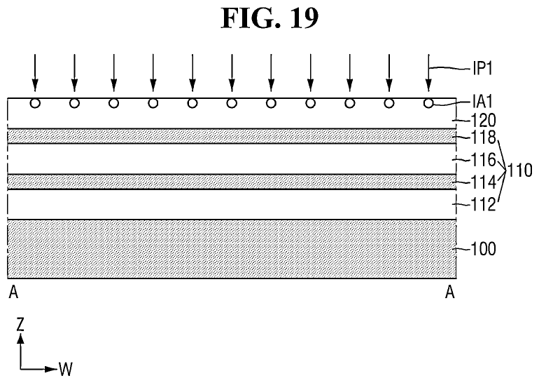

Referring to FIG. 18, the reflective structure 110 is formed on the substrate 100. For example, the first reflective layers 112 and 115 and the second reflective layers 114 and 118 having different refractive indexes may be alternately stacked on the substrate 100. Then, referring to FIG. 19, the first spacer layer 120 is formed on the reflective structure 110, and a first doping process IP1 is performed. The first spacer layer 120 may extend along the upper side of the reflective structure 110. The first spacer layer 120 may include an insulating material, for example, but not limited to, at least one of silicon oxide, silicon nitride, silicon oxynitride, and combinations thereof. As an example, the first spacer layer 120 may be a silicon oxide film (SiO₂). The first doping process IP1 may be performed on the upper side of the first spacer layer 120. As the first doping process IP1 is performed, a first impurity IA1 of a first conductivity type may be doped in at least a part of the first spacer layer 120. As an example, when the first conductivity type is p-type, the first impurity IA1 may include a p-type impurity (e.g., boron (B), aluminum (Al) or gallium (Ga)). The first doping process IP1 may include, for example, but not limited to, an ion implantation process.

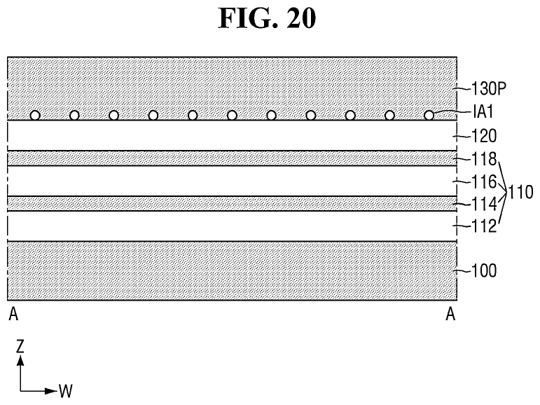

Referring to FIG. 20, a first preliminary photodiode layer 130P is formed on the first spacer layer 120. The first preliminary photodiode layer 130P may include an intrinsic semiconductor material which is not doped with impurity. As an example, the first preliminary photodiode layer 130P may be made of i-Si (intrinsic Si). As the first preliminary photodiode layer 130P is formed, at least a part of the first impurity IA1 in the first spacer layer 120 may be diffused toward the first preliminary photodiode layer 130P. For example, a lower part of the first preliminary photodiode layer 130P may include the first impurity IA1.

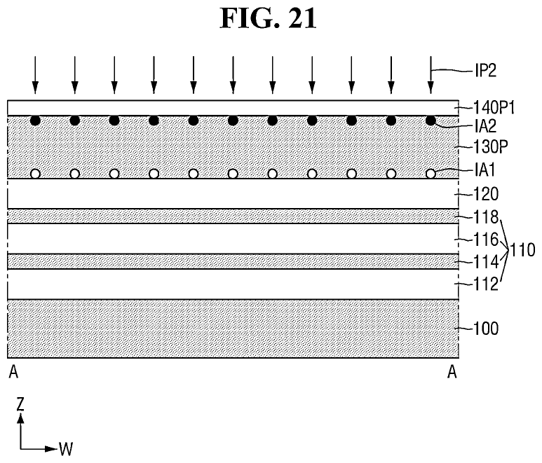

Referring to FIG. 21, a first preliminary spacer layer 140P1 is formed on the first preliminary photodiode layer 130P, and a second doping process IP2 is performed. The first preliminary spacer layer 140P1 may extend along the upper side of the first preliminary photodiode layer 130P. The first preliminary spacer layer 140P1 may include an insulating material, for example, but not limited to, at least one of silicon oxide, silicon nitride, silicon oxynitride, and combinations thereof. As an example, the first spacer layer 140P1 may be a silicon oxide film (SiO₂).

The second doping process IP2 may be performed on the upper side of the first preliminary spacer layer 140P1. As the second doping process IP2 is performed, a second impurity IA2 of the second conductivity type may be doped in at least a part of the first preliminary photodiode layer 130P. As an example, when the second conductivity type is n-type, the second impurity IA2 may include an n-type impurity (e.g., phosphorus (P), arsenic (As) or antimony (Sb)). The thickness of the first preliminary spacer layer 140P1 may be appropriately controlled so that the second impurity IA2 may be doped to a predetermined depth inside the first preliminary photodiode layer 130P. For example, the thickness of the first spacer layer 140P1 may be, but not limited to, about 50 nm. The second doping process IP2 may include, for example, but not limited to, an ion implantation process.

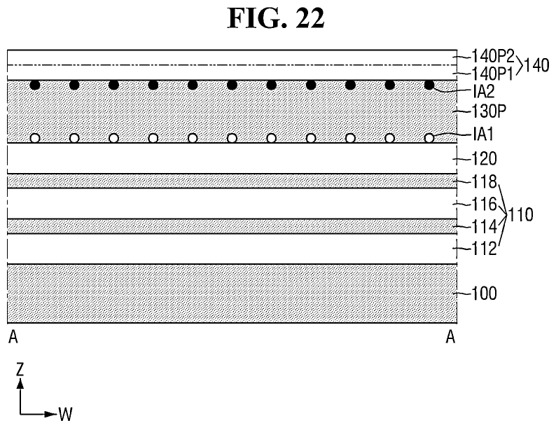

Referring to FIG. 22, a second preliminary spacer layer 140P2 is formed on the first preliminary spacer layer 140P1. The second preliminary spacer layer 140P2 may extend along the upper side of the first preliminary spacer layer 140P1. Accordingly, the second spacer layer 140 including the first preliminary spacer layer 140P1 and the second preliminary spacer layer 140P2 may be formed. The thickness of the second spacer layer 140P2 may be appropriately controlled so that the second spacer layer 140 may be formed to a predetermined thickness. The second preliminary spacer layer 140P2 may include the same material as the first preliminary spacer layer 140P1, or may include a material different from the first preliminary spacer layer 140P1.

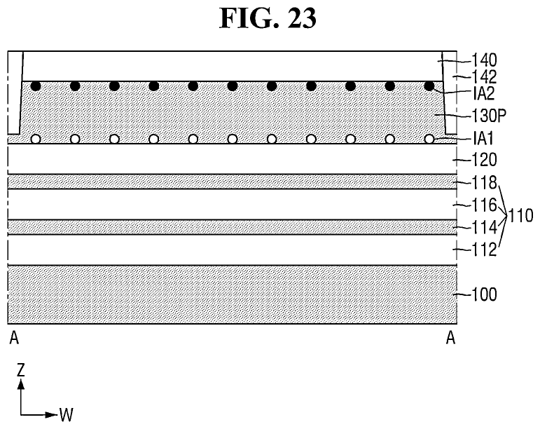

Referring to FIG. 23, the element isolation pattern 142 is formed. The element isolation pattern 142 may define a plurality of third PIN photodiodes 130 and/or a plurality of unit pixels PX, which will be described below. Although it is only shown that the element isolation pattern 142 does not completely cut the first preliminary photodiode layer 130P, this is only an example, and the element isolation pattern 142 may of course completely cut the first preliminary photodiode layer 130P.

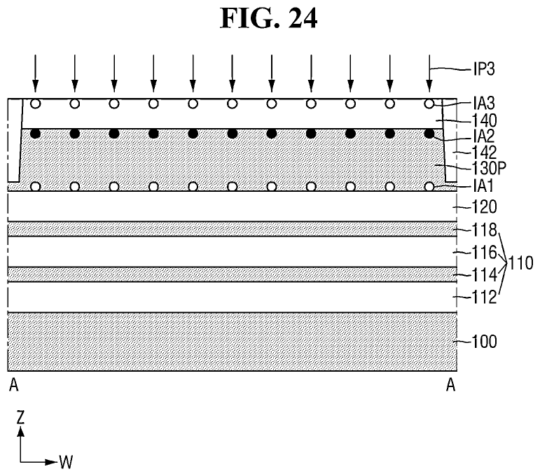

Referring to FIG. 24, a third doping process IP3 is performed. The third doping process IP3 may be performed on the upper side of the second spacer layer 140. As the third doping process IP3 is performed, a third impurity IA3 of the first conductivity type may be doped in at least a part of the second spacer layer 140. As an example, when the first conductivity type is p-type, the third impurity IA3 may include a p-type impurity (e.g., boron (B), aluminum (Al) or gallium (Ga)). The third doping process IP3 may include, for example, but not limited to, an ion implantation process.

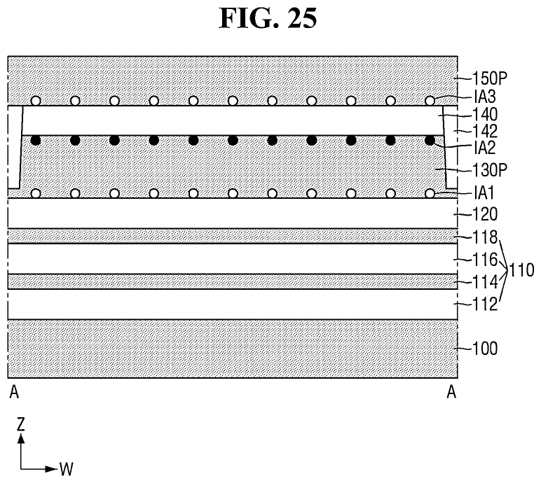

Referring to FIG. 25, a second preliminary photodiode layer 150P is formed on the second spacer layer 140. The second preliminary photodiode layer 150P may include an intrinsic semiconductor material which is not doped with an impurity. As an example, the second preliminary photodiode layer 150P may be made of i-Si (intrinsic Si). As the second preliminary photodiode layer 150P is formed, at least a part of the third impurity IA3 in the second spacer layer 140 may be diffused toward the second preliminary photodiode layer 150P. For example, a lower part of the second preliminary photodiode layer 150P may include a third impurity IA3.

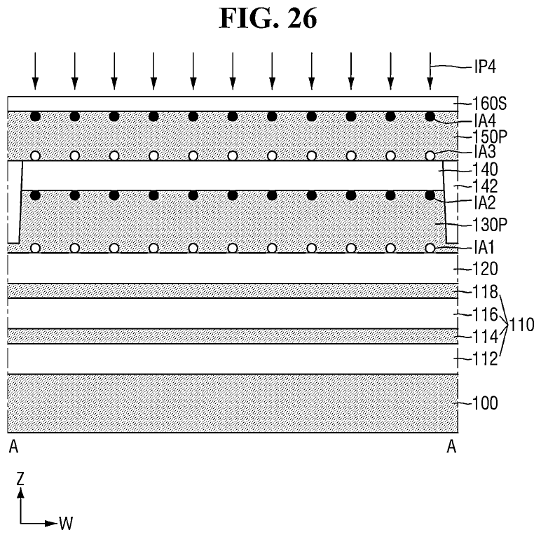

Referring to FIG. 26, a sacrificial layer 160S is formed on the second preliminary photodiode layer 150P, and a fourth doping process IP4 is performed. The sacrificial layer 160S may extend along the upper side of the second preliminary photodiode layer 150P. The sacrificial layer 160S may include an insulating material, for example, but not limited to, at least one of silicon oxide, silicon nitride, silicon oxynitride, and combinations thereof. As an example, the sacrificial layer 160S may be a silicon oxide film (SiO₂).

The fourth doping process IP4 may be performed on the upper side of the sacrificial layer 160S. As the fourth doping process IP4 is performed, a fourth impurity IA4 of the second conductivity type may be doped in at least a part of the second preliminary photodiode layer 150P. As an example, when the second conductivity type is n-type, the fourth impurity IA4 may include an n-type impurity (e.g., phosphorus (P), arsenic (As) or antimony (Sb)). The thickness of the sacrificial layer 160S may be appropriately controlled so that the fourth impurity IA4 may be doped into the second preliminary photodiode layer 150P to a predetermined depth. For example, the thickness of the sacrificial layer 160S may be, but not limited to, about 50 nm. The fourth doping process IP4 may include, for example, but not limited to, an ion implantation process. After the fourth doping process IP4 is performed, the sacrificial layer 160S may be removed.

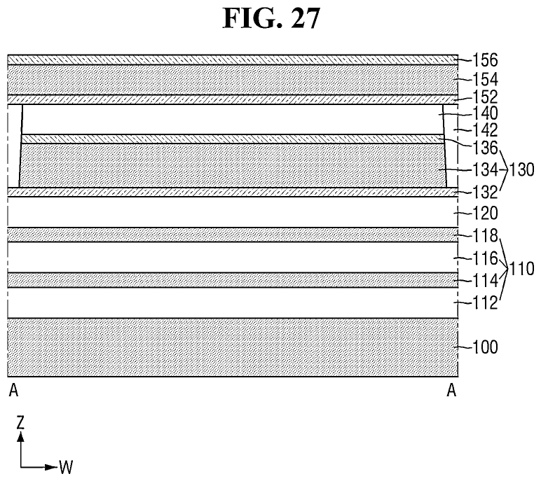

Referring to FIG. 27, a heat treatment process is performed; and, as the heat treatment process is performed, the first impurity IA1 and the second impurity IA2 may be diffused and crystallized inside the first preliminary photodiode layer 130P. Accordingly, the third PIN photodiode 130 including the first impurity semiconductor layer 132, the first intrinsic semiconductor layer 134, and the second impurity semiconductor layer 136 may be formed. Furthermore, as the heat treatment process is performed, the third impurity IA3 and the fourth impurity IA4 may be diffused and crystallized inside the second preliminary photodiode layer 150P. Accordingly, the third impurity semiconductor layer 152, the second intrinsic semiconductor layer 154, and the fourth impurity semiconductor layer 156 which are sequentially stacked on the second spacer layer 140 may be formed. The heat treatment process may include, for example, but not limited to, rapid thermal processing (RTP). The RTP process may be performed, for example, but not limited to, at about 1000° C. for about 10 seconds.

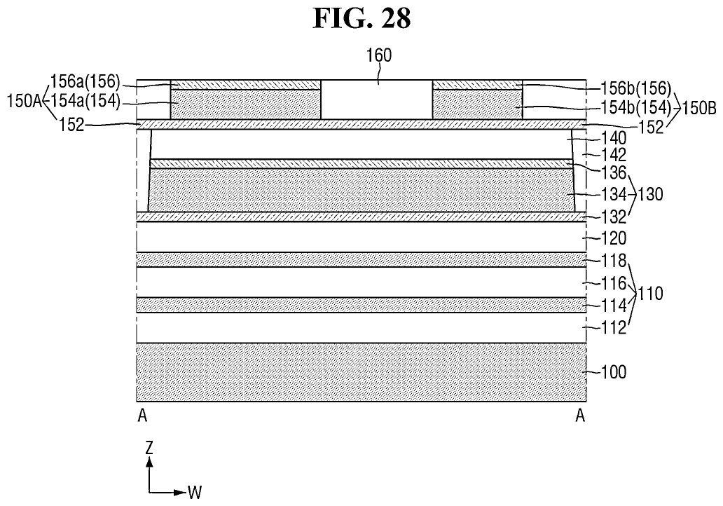

Referring to FIG. 28, the second intrinsic semiconductor layer 154 and the fourth impurity semiconductor layer 156 are patterned to form the first PIN photodiode 150A and the second PIN photodiode 150B. Accordingly, the first PIN photodiode 150A and the second PIN photodiode 150B each including the third impurity semiconductor layer 152, the second intrinsic semiconductor layer 154, and the fourth impurity semiconductor layer 156 may be formed. Although the third impurity semiconductor layer 152 is only shown as not being patterned, this is merely an example, and the third impurity semiconductor layer 152 may be pattern together with the second intrinsic semiconductor layer 154 and the fourth impurity semiconductor layer 156.

After the first PIN photodiode 150A and the second PIN photodiode 150B are formed, a first interlayer insulating film 160 that fills a space between the first PIN photodiode 150A and the second PIN photodiode 150B may be formed. Next, referring to FIG. 3, the transparent electrode layers 170A and 170B and the second interlayer insulating film 180 are formed on the first PIN photodiode 150A and the second PIN photodiode 150B. Accordingly, the image sensor described above using FIGS. 1 to 11 may be fabricated.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

1. An image sensor, comprising:
an array of unit pixels respectively including:
first, second and third PIN photodiodes having respective first, second and third widths, which are unequal to each other, and respective first, second and third absorption spectra associated therewith, which are unequal to each other; and
wherein the first absorption spectra is a first linear combination of three color matching functions divided by a wavelength of light incident the image sensor, the second absorption spectra is a second linear combination of the three color matching functions divided by a wavelength of light incident the image sensor, and the third absorption spectra is a third linear combination of the three color matching functions divided by a wavelength of light incident the image sensor.

2. The image sensor of claim 1, wherein a period at which the plurality of unit pixels are arranged is smaller than a wavelength of visible light.

3. The image sensor of claim 1, wherein the three color matching functions are CIE XYZ color matching functions.

4. The image sensor of claim 1, wherein the first PIN photodiode and the second PIN photodiode extend on an upper side of the third PIN photodiode.

5. The image sensor of claim 4, wherein a period at which the plurality of unit pixels are arranged is in a range from 198 nm to 242 nm; wherein the first width is in a range from 111 nm to 137 nm; and wherein the second width is in a range from 72 nm to 88 nm.

6. The image sensor of claim 4, further comprising:
a first transparent electrode pattern connected to an upper side of the first PIN photodiode; and
a second transparent electrode pattern connected to an upper side of the second PIN photodiode.

7. An image sensor, comprising:
a plurality of unit pixels arranged two-dimensionally, with each unit pixel comprising:
a first spacer layer on a substrate;
a first PIN photodiode on the first spacer layer;
a second spacer layer on the first PIN photodiode;
a second PIN photodiode, which overlaps the first PIN photodiode, extending on the second spacer layer and having a first width;
a third PIN photodiode, which overlaps the first PIN photodiode, extending on the second spacer layer and having a second width different from the first width; and
a transparent electrode layer extending on the second and third PIN photodiodes.

8. The image sensor of claim 7, wherein a period at which the plurality of unit pixels are arranged is in a range from 198 nm to 242 nm.

9. The image sensor of claim 8, wherein the first width is in a range from 111 nm to 137 nm; and wherein the second width is in a range from 72 nm to 88 nm.

10. The image sensor of claim 7, wherein a thickness of the first PIN photodiode is in a range from 136 nm to 168 nm.

11. The image sensor of claim 10, wherein the first PIN photodiode comprises:
an intrinsic semiconductor layer extending between the first spacer layer and the second spacer layer;
a first impurity semiconductor layer doped with an impurity of a first conductivity type, extending between the first spacer layer and the intrinsic semiconductor layer; and
a second impurity semiconductor layer doped with an impurity of a second conductivity type different from the first conductivity type, extending between the second spacer layer and the intrinsic semiconductor layer; and
wherein each of the first and second impurity semiconductor layers has a respective thickness of 15 nm or less.

12. The image sensor of claim 10, wherein a thickness of the first spacer layer is in a range from 109 nm to 135 nm.

13. The image sensor of claim 7, wherein each of the second and third PIN photodiodes has a respective thickness in a range from 131 nm to 161 nm.

14. The image sensor of claim 13, wherein each of the second and third PIN photodiodes comprises:
an intrinsic semiconductor layer extending between the second spacer layer and the transparent electrode layer;
a first impurity semiconductor layer doped with an impurity of a first conductivity type, extending between the second spacer layer and the intrinsic semiconductor layer; and
a second impurity semiconductor layer doped with an impurity of a second conductivity type different from the first conductivity type, extending between the transparent electrode layer and the intrinsic semiconductor layer; and
wherein each of the first and second impurity semiconductor layers has a respective thickness of 15 nm or less.

15. The image sensor of claim 13, wherein a thickness of the second spacer layer is in a range from 85 nm to 105 nm.

16. The image sensor of claim 7, wherein the absorption spectra of the first, second and third PIN photodiodes are expressed as different independent linear combinations of functions obtained by dividing each of three color matching functions by wavelength.

17. An image sensor, comprising:
a substrate;
a plurality of first PIN photodiodes arranged on the substrate in a first grid pattern that spans a first direction and a second direction, which are parallel to an upper side of the substrate and intersect each other;
a plurality of second PIN photodiodes arranged on the substrate in a second grid pattern that spans the first direction and the second direction, and is offset relative to the first grid pattern; and
a plurality of third PIN photodiodes arranged on the substrate such that each of the third PIN photodiodes overlaps at least one of the plurality of first PIN photodiodes and at least one of the plurality of second PIN photodiodes in a third direction orthogonal to the first and second directions; and
wherein a first width of each of the first PIN photodiodes is different from a second width of each of the second PIN photodiodes.

18. The image sensor of claim 17, wherein a period at which the plurality of first PIN photodiodes are arranged in the first direction and the second direction is in a range from 198 nm to 242 nm.

19. The image sensor of claim 18, wherein the first width is in a range from 111 nm to 137 nm, and the second width is in a range from 72 nm to 88 nm.

20. The image sensor of claim 17, wherein the absorption spectra of the first to third PIN photodiodes are expressed as respective different independent linear combinations of functions obtained by dividing each of three color matching functions by wavelength.

21.-26. (canceled)
